(19) United States
(12) Patent Application Publication
(10) Pub. No.: US 2026/0262156 A1
(43) Pub. Date: Sep. 3, 2026

(54) EUV RADIATION SOURCE AND POSITION-CONTROLLABLE MIRROR

(71) Applicant: ASML Netherlands B.V., Veldhoven (NL)

(72) Inventors: Robert Rens WAIBOER, Veldhoven (NL); Dieter Emmanuel LAMBREGTS, Eindhoven (NL); Jordy NIEUWHOFF, Valkenswaard (NL); Jasper WINTERS, Nieuw Vennep (NL); Albert DEKKER, Delft (NL); Kodai HATAKEYAMA, Pijnacker (NL); Robert Jan VOORHOEVE, The Hague (NL); Robert Max EGERMAN, Delfgauw (NL)

(73) Assignee: ASML Netherlands B.V., Veldhoven (NL)

(21) Appl. No.: 19/163,307

(22) PCT Filed: Mar. 1, 2024
(86) PCT No.: PCT/EP2024/055415

§ 371 Date: Sep. 8, 2025

(30) Foreign Application Priority Data
Mar. 23, 2023 (EP) 23163835.4

(51) Int. Cl. H05G 2/00; G02B 26/08; G03F 7/00

(52) U.S. Cl. CPC H05G 2/0084; G02B 26/0816; G03F 7/70033; H05G 2/0086

(57) ABSTRACT

An EUV radiation source comprising a laser configured to emit a laser beam, and an optical system configured to control a position of the laser beam such that it is incident upon fuel droplets, wherein the optical system comprises an optical path which includes a position-controllable mirror having a control bandwidth of at least 500 Hz.

### CROSS-REFERENCE TO RELATED APPLICATIONS

This application claims priority of EP application 23163835.4 which was filed on 23 Mar. 2023 and which is incorporated herein in its entirety by reference.

### FIELD

The present invention relates to a an EUV radiation source and to a position-controllable mirror.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

A lithographic apparatus together with an EUV radiation source may be referred to as a lithographic system.

The EUV radiation source may be a laser produced plasma (LPP) system. In an LPP system, a laser is used to deposit laser energy into a fuel material. The deposition of laser energy into the fuel material creates a plasma. EUV radiation is emitted from the plasma during de-excitation and recombination of electrons with ions of the plasma.

An LPP system may use two laser beams, a main pulse laser beam and a pre-pulse laser beam, to generate EUV radiation from a fuel material. The pre-pulse laser beam provides some energy into a droplet of fuel material, causing the fuel material to expand. The fuel material may also change shape, e.g., change from spherical to a disk-like shape. The main pulse laser beam is then incident upon the fuel material, generating EUV emitting plasma.

A problem that may arise in an EUV radiation source is that misalignment of the pre-pulse laser beam with respect to a droplet of fuel material occurs. This will cause a significant reduction of the amount of EUV radiation that is provided by that droplet of fuel material.

### SUMMARY

It is an object of the invention to provide an EUV radiation source and a position-controllable mirror that overcome a disadvantage associated with the prior art.

According to a first aspect of the present disclosure there is provided an EUV radiation source comprising a laser configured to emit a laser beam, and an optical system configured to control a position of the laser beam such that it is incident upon fuel droplets, wherein the optical system comprises an optical path which includes a position-controllable mirror having a control bandwidth of at least 500 Hz.

Because the position-controllable mirror has a bandwidth of at least 500 Hz, it is able to more direct the laser beam onto fuel droplets more accurately. This increases the amount of EUV radiation that is provided by the fuel droplets.

According to a second aspect of the invention, there is provided a position-controllable mirror for use in an EUV radiation source, wherein the position-controllable mirror has a control bandwidth of at least 500 Hz.

The position-controllable mirror may have a control bandwidth of at least 1 kHz.

The EUV radiation source may further comprise a controller configured to control tilt of the position-controllable mirror, wherein the controller is configured to control the position-controllable mirror to at least partially compensate for laser beam position errors arising from an actuatable optical device in the optical path which has a lower bandwidth of control than the position-controllable mirror. Additionally, the controller may be configured to control, both tip and tilt of the position-controllable mirror.

The position-controllable mirror may comprise a plurality of optical encoders.

The optical encoders may include encoder scales provided on radially extending arms of an encoder support.

The optical encoders may include encoder scales provided on a side wall of a mirror substrate of the position-controllable mirror.

The encoder scales may be convex.

The encoder scales may have a radius of curvature which generally corresponds with a radial distance from the encoder scales to a central axis of the position-controllable mirror.

The position-controllable mirror may comprise a hybrid reluctance actuator formed from an actuator yoke and a stator, each of which comprises a plurality of radially extending arms.

At least one of the actuator yoke and the stator may be formed from soft magnetic composite.

The stator may be formed from soft magnetic composite. The stator may further comprise pillars which extend perpendicularly from the radially extending stator arms. The pillars may be integrally formed with the radially extending arms.

At least one of the actuator yoke and the stator may be formed from laminated ferrous material.

The laminations of the radially extending arms of the stator may be perpendicular to a central axis of the position-controllable mirror.

The stator may further comprise pillars which extend perpendicularly from the radially extending arms. Laminations of the pillars may be parallel with the central axis of the position-controllable mirror.

The pillars may extend through openings provided in the radially extending stator arms.

The position-controllable mirror may further comprise a clamp configured to clamp together the actuator yoke and radial projections which project from a stem of the mirror.

The clamp may also clamp an encoder support together with the actuator yoke and the radial projections which project from the stem of the mirror.

The mirror may comprise a substrate provided with a reflective surface, and wherein the mirror substrate comprises at least one of: one or more hollow volumes, one or more undercuts, a variable wall thickness.

The position-controllable mirror may further comprise a bendable stem which connects the mirror to a base.

The bendable stem may have a narrowed diameter portion.

A centre of gravity of a moveable part of the position-controllable mirror may be located at the narrowed diameter portion of the bendable stem.

A centre of gravity of a moveable part of the position-controllable mirror may corresponds with a centre of elasticity of the moveable part of the position-controllable mirror.

The position-controllable mirror may further comprise a flexure located below the mirror and above the actuator yoke.

The flexure may comprise a plurality of connections between an inner portion and an outer portion, the connections including a bend.

The flexure may comprise a plurality of connections between an inner portion and an outer portion, the connections being U-shaped.

The position-controllable mirror may be configured for use in a vacuum environment.

A mirror body of the position controllable mirror may be formed from ceramic material.

The position-controllable mirror may include adjustable end stops.

The position controllable mirror may include a heat dump.

The position controllable mirror may further comprise an encoder head and locking system, wherein the locking system comprises a leaf spring and an actuator. The actuator may be configured to engage the leaf spring with an encoder head holder. The leaf spring may lie in a plane which is generally parallel to a central axis of the position-controllable mirror.

The encoder head holder may further comprise a plate configured to be sandwiched between the leaf spring and a housing wall of the position-controllable mirror.

The actuator may comprise a chamfered block which is threadingly engaged with a bolt, the chamfered block being located within an opening in the housing wall.

According to a third aspect of the invention there is provided a method of directing a laser beam onto a fuel target in an EUV radiation source, wherein the method comprises controlling the position of the laser beam using a position-controllable mirror having a control bandwidth of at least 500 Hz.

Because the position-controllable mirror has a bandwidth of at least 500 Hz, it is able to more direct the laser beam onto fuel droplets more accurately. This increases the amount of EUV radiation that is provided by the fuel droplets.

The position controllable mirror may be in an optical path together with at least one actuatable optical device. The position-controllable mirror may be tilted to at least partially compensate for laser beam position errors arising from a lower control bandwidth of the actuatable optical device compared with the control bandwidth of the position-controllable mirror.

The method of the third aspect of the invention may include features of the first and second aspects of the invention.

Features of different aspects of the invention may be combined together.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus and an EUV radiation source according to an embodiment of the present disclosure;

FIG. 2 schematically depicts an optical system which forms part of the EUV radiation source;

FIG. 3 depicts in a partially exploded perspective view a position-controllable mirror according to an embodiment of the present disclosure;

FIG. 4 depicts the position-controllable mirror of FIG. 3 in a cross-sectional perspective view;

FIG. 5 depicts a stator of the position-controllable mirror;

FIG. 6 depicts in cross-section a moveable part of the position-controllable mirror; and

FIG. 7 depicts a flexure of the position-controllable mirror;

FIG. 8 depicts in perspective view an encoder head and locking system;

FIGS. 9A-C depict adjustment of the height of the encoder head 600 and locking of the encoder head in position.

### DETAILED DESCRIPTION

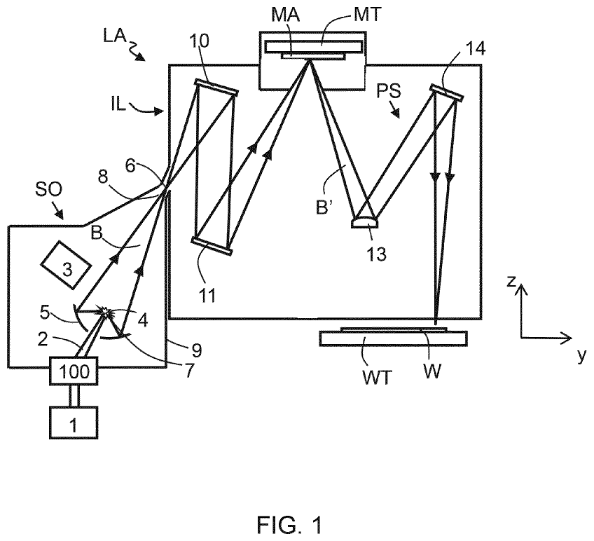

FIG. 1 shows a lithographic system which comprises a radiation source SO according to an embodiment of the disclosure, and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e., a small amount of gas (e.g., hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1 may comprise a pre-pulse laser system. The pre-pulse laser system may, for example, comprise a Nd:YAG laser (or another laser configured to provide a laser beam with a wavelength of around 1 micron). The laser system 1 may include a main-pulse laser system. The main-pulse laser system may, for example, comprise a CO₂ laser (or other laser configured to provide a laser beam with a wavelength of around 10 microns). Embodiments of the present disclosure relate to the pre-pulse laser system.

The laser system 1 is arranged to deposit energy via a pre-pulse laser beam and a main laser beam (depicted as a single laser beam 2) into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g., in the form of droplets, along a trajectory towards a plasma formation region 4. The laser beam 2 is incident upon the tin at the plasma formation region 4. The pre-pulse laser beam provides some energy into the tin, causing the tin to expand. The tin may also change shape, e.g., change from spherical to a disk-like shape. The main pulse laser beam is then incident upon the tin.

The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source, or a free electron laser (FEL) may be used to generate EUV radiation.

Also depicted in FIG. 1 is an optical system 100 which may form part of an embodiment of the disclosure. The optical system 100 may be configured to control a position of the pre-pulse laser beam 2 such that it is incident upon fuel droplets. The optical system 100 comprises a position-controllable mirror according to an embodiment of the disclosure.

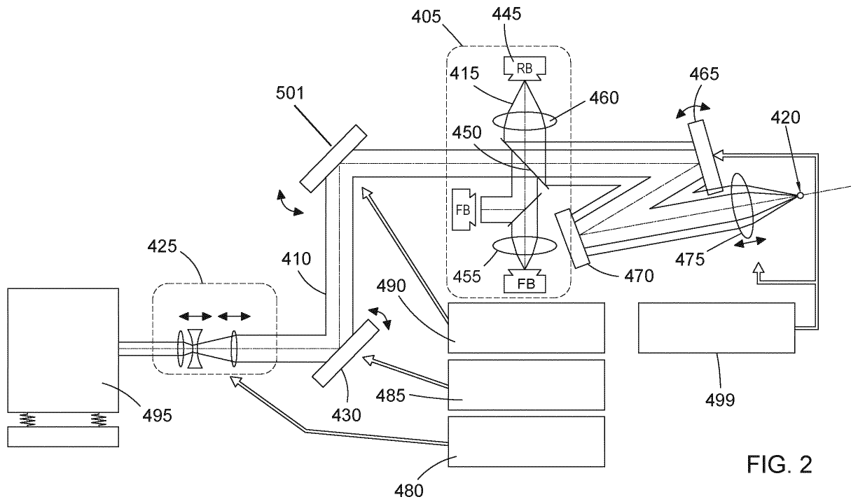

FIG. 2 depicts an example of the optical system 100. The optical system includes a position-controllable mirror according to an embodiment of the disclosure. The optical system 100 may be referred to as a metrology and control system 100.

The metrology and control system 100 comprises an optical pickup 405. The optical pickup 405 is configured to measure a forward beam 410 (laser beam) directed towards a target location 420 and a return beam 415 reflected from the target location 420. The forward beam 410 may be a pre-pulse laser beam 2 and the target location may be a plasma formation location (see FIG. 1). The laser beam 410 travels along an optical path which comprises a plurality of optical devices, at least one of which is a position-controllable mirror according to an embodiment of the disclosure.

The metrology and control system 100 comprises a plurality of actuatable optical devices 425, 430, 465, 475, 501 that are configurable to direct and focus the forward beam 410 onto the target location 420 and align a measurement plane of the optical pickup 405 with the target location 420, as described in more detail below. In particular, actuatable optical devices 425, 430, 465, 475, 501 are disposed both before and after the optical pickup 405 in a path of the forward beam 410, and the actuatable optical devices are controlled in response to a measurement of the forward beam 410 and the return beam 415 by the optical pickup 405.

The example metrology and control system 100 comprises a pre-pulse laser 495 configured to provide the forward beam 410. The pre-pulse laser 495 may be used to optimize a mass density and/or distribution of a fuel in an EUV radiation source, prior to interaction with a subsequent main pulse.

The example metrology and control system 100 of FIG. 2 comprises a first actuatable optical device 425. The first actuatable optical device 425 is disposed before the optical pickup 405 in a path of the forward beam 410. The first actuatable optical device 425 is controlled by a first actuatable optical device controller 480.

The first actuatable optical device 425 is configurable for controlling a wavefront curvature of the forward beam 410. In examples, the first actuatable optical device 425 may additionally or alternatively configured to control a diameter of the forward beam 410.

As such the first actuatable optical device controller 480 is denoted “Beam-spatial d, c controller” in FIG. 2, wherein “d” refers to a diameter of the forward beam 410 and “c” refers to a curvature of a wavefront of the forward beam 410.

The first actuatable optical device 425 may comprise a plurality of devices, such as one or more lenses. A position and/or property of the first actuatable optical device 425 may be configurable, e.g., actuatable. That is, a position and/or property of one or more of the plurality of devices forming the first actuatable optical device 425 may be configurable.

In an example, the first actuatable optical device 425 may comprise one or more lenses, where a position of the one or more lenses may be adjusted. That is, the first actuatable optical device 425 may comprise one or more position-controllable lenses. An actuator, such as a servo motor, may be configurable to control a position of the one or more lenses.

The example metrology and control system 100 comprises a second actuatable optical device 430. The second actuatable optical device 430 is disposed before the optical pickup 405 in a path of the forward beam 410. The second actuatable optical device 430 is disposed after the first actuatable optical device 425 in the path of the forward beam 410. The second actuatable optical device 430 is controlled by a second actuatable optical device controller 485.

The second actuatable optical device 430 is a mirror, e.g., a reflective surface suitable for reflecting radiation having a wavelength of the forward beam 410.

In the examples, the second actuatable optical device 430 is a position-controllable mirror. That is, a tilt of the second actuatable optical device 430 may be adjusted by an actuator, such as a servo motor or the like. The second actuatable optical device 430 may be tilted in two directions, In use, the second actuatable optical device 430 may be configured to compensate for an offset in the forward beam 410 relative to an optical axis of the second actuatable optical device 430. That is, actuation of the second actuatable optical device 430 to control an offset of the forward beam 410 may be controlled in response to a measurement of the forward beam 410 by the optical pickup 405, wherein a measurement of the forward beam 410 and the return beam 415 by the optical pickup 405 may comprise a measurement of the wavefront and/or position of the forward beam 410 and the return beam 415.

As such the second actuatable optical device controller 485 is denoted “Beam position X-Y controller” in FIG. 2, wherein the controller 185 configures the second actuatable optical device 430 to adjust a position of the forward beam 410 in an X-Y plane to compensate for the offset in the forward beam 410

The example metrology and control system 100 comprises a third actuatable optical device 501. The third actuatable optical device 501 is disposed before the optical pickup 405 in a path of the forward beam 410. The third actuatable optical device 501 is controlled by a third actuatable optical device controller 490.

The third actuatable optical device 501 is a mirror for reflecting the forward beam 410. In the examples, the third actuatable optical device 501 is a position-controllable mirror. That is, a tilt of the third actuatable optical device 501 may be adjusted. The tilt may be adjusted in two directions. The position-controllable mirror 501 may be according to an embodiment of the disclosure. The position-controllable mirror 501 is described further below. More than one of the actuatable optical devices may be a position-controllable mirror according to an embodiment of the invention.

In use, the position-controllable mirror 501 may be configured to compensate for a tilt in the forward beam 410 relative to an optical axis. Actuation of the position-controllable mirror 501 to compensate for the effects of a tilt in the forward beam 410 may be controlled in response to a measurement of the forward beam 410 and the return beam 415 by the optical pickup 405.

The second actuatable optical device 430 and/or the third actuatable optical device 501 may be a position-controllable mirror according to an embodiment of the disclosure.

The third actuatable optical device controller 490 is denoted “Beam tilt Rx, Ry controller” in FIG. 2, wherein the third actuatable optical device controller 490 configures the position-controllable mirror 501 to compensate for a tilt in the forward beam 410.

Although FIG. 2 shows only two position-controllable mirrors 430, 501 before the optical pickup 405 in the path of the forward beam 410, it will be appreciated that this is for purposes of example only, and in other examples more position-controllable mirrors may be provided. One or more of the position-controllable mirrors may be according to an embodiment of the disclosure.

The optical pickup 405 comprises a first sensor 440 for measuring the forward beam 410, a second sensor 445 for measuring the return beam 415, a beam-splitting device 450 for directing a portion of the forward beam 410 onto the first sensor 440, and a reflective surface for directing the return beam 415 onto the second sensor 445. The optical pickup 405 also comprises a first focusing device 455 for focusing the forward beam 410 on the first sensor 440 and a second focusing device 460 for focusing the return beam 415 on the second sensor 455.

The first sensor 440, second sensor 445, beam-splitting device 450, reflective surface, first focusing device 455 and second focusing device 460 may be conventional and are therefore for brevity are not described in detail here.

The example metrology and control system 100 also comprises a fourth actuatable optical device 465. The fourth actuatable optical device 465 is disposed after the optical pickup 405 in the path of the forward beam 410. The fourth actuatable optical device 465 is disposed in the path of the return beam 415.

The fourth actuatable optical device 465 is a mirror for reflecting the forward beam 410, and the return beam 415. In the examples, the fourth actuatable optical device 465 is a position-controllable mirror (and may be a mirror according to an embodiment of the disclosure).

As such, the fourth actuatable optical device 465 together with the second actuatable optical device 430 and the third actuatable optical device 501 may effectively be used for steering the forward beam 410.

Furthermore, the fourth actuatable optical device 465 is configurable to center the return beam 415 on the second sensor 445 of the optical pickup 405. By centering the return beam 415 on the second sensor 445, a range required by the second sensor 445 may be minimized, and the second sensor 445 may be operated close to the center of an available range, and within a region of the sensor exhibiting a relatively high linear response.

A further optical device 470 in the path of the forward beam 410 and return beam 415 is also depicted, wherein for purposes of example the further optical device 470 is a mirror (and may be a mirror according to an embodiment of the disclosure).

The example metrology and control system 100 also comprises a fifth actuatable optical device 475. The fifth actuatable optical device 475 is disposed after the optical pickup 405 in the path of the forward beam 410. The fifth actuatable optical device 475 is disposed in the path of the return beam 415.

Although only two actuatable devices 465, 475 (e.g., position-controllable mirrors or lenses) are depicted after the optical pickup 405 in the path of the forward beam 410 and the return beam 415, it will be appreciated that this is for purposes of example only, and in other examples one or more additional position-controllable mirrors or lenses may be provided. One or more of the position-controllable mirrors may be according to an embodiment of the disclosure.

The fifth actuatable optical device 475 is disposed after the optical pickup 405 in the path of the forward beam 410 and the return beam 415. In the example, the fifth actuatable optical device 475 is disposed after the fourth actuatable optical device 465 in the path of the forward beam 410.

The example fifth actuatable optical device 475 comprises an actuatable lens. In use, the fifth actuatable optical device 475 may be actuated to focus the forward beam 410 on a fuel at the target location 410, thereby also ensuring the measurement plane of the optical pickup 405 is aligned with the target location 410.

Furthermore, an optical focal length of the fifth actuatable optical device 475 is configured to match that of the first focusing device 455 and the second focusing device 460 of the optical pickup 405. As such, by actuating the fifth actuatable optical device 475 to focus the forward beam 410 on the fuel at the target location 410, e.g. ensuring the target location 410 is exactly in the back focal plane, then both the first focusing device 455 and the second focusing device 460, which match the forward beam 410 focal length, may provide an indication that a location of a focal point of the forward beam 410 is exactly at the target location 420.

The fourth and fifth actuatable optical devices 465, 475 are controlled by a fourth actuatable optical device controller 499. The fourth actuatable optical device controller 499 is denoted “Laser to droplet X, Y, Z controller” in FIG. 2, because the fourth controller 499 may actuate the fourth and fifth actuatable optical devices 465, 475 to control steering and positioning of a focal point of the forward beam 410 in the x, y, and z directions.

That is, the fourth and fifth actuatable optical devices 465, 475 may control the position of a focal point of the forward beam 410 in the x, y, and z directions to ensure the forward beam 410 is precisely incident upon a fuel at the target location to optimize an EUV plasma generation process in an EUV radiation source. By controlling the focal point of the forward beam 410 as such, the fourth and fifth actuatable optical devices 465, 475 also ensure that the return beam 415 reflected by the fuel at the target location 420 may be directed towards a center of the second sensor 445.

The fourth actuatable optical device 465 may have a lower bandwidth of control than the third actuatable optical device 501. A control error arising from this lower bandwidth of control may be fed through from the fourth controller 499 to the third controller 490. The third controller 490 may move the third actuatable optical device 501 to compensate for the lower bandwidth of control of the fourth actuatable optical device 465.

In general, a controller may be configured to control a position-controllable mirror according to an embodiment of the disclosure, in order to at least partially compensate for laser beam position errors arising from an actuatable optical device having a lower bandwidth of control than the position-controllable mirror. In this context, laser beam position errors may be interpreted as meaning deviation of the laser beam from a desired position where the laser beam is incident upon a fuel droplet.

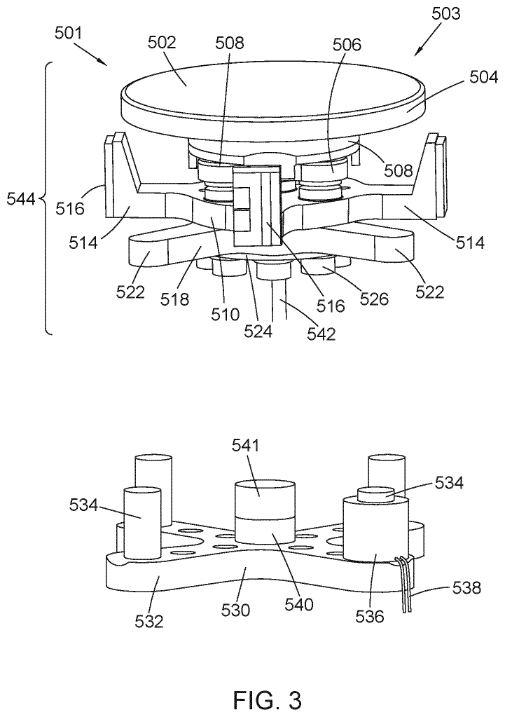

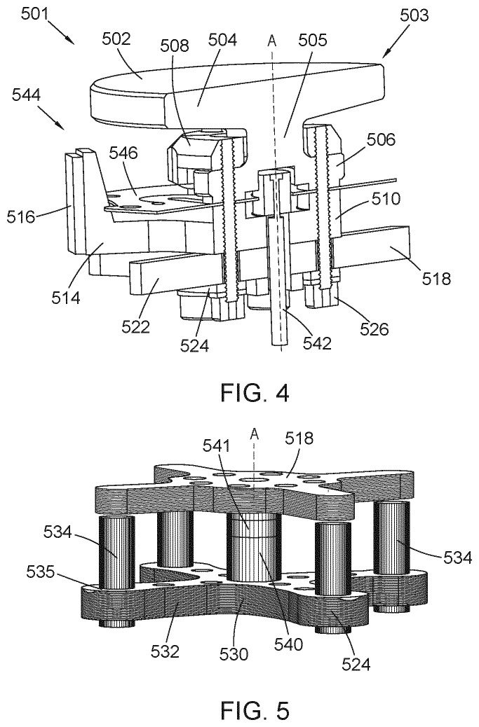

FIG. 3 depicts in a perspective partially exploded view the position-controllable mirror 501 according to an embodiment of the disclosure. FIG. 4 depicts in cross-section a moveable part 544 of the position-controllable mirror. The position-controllable mirror 501 has a central axis A.

The position-controllable mirror comprises a reflective surface 502 provided on a substrate 504. The substrate may for example be formed from ceramic material such as silicon clad Silicone Carbide or may be a metal such as aluminium. The substrate may for example be diamond filled Silicone Carbide. The reflective surface 502 may for example be formed as a multilayer structure (e.g., a hafnia/silica multilayer structure). A stem 505 extends downwardly from the substrate 504. The stem 505 may be integrally formed with the substrate 504. Radial projections 506 extend from the stem 505. The radial projections 506 may be integrally formed with the stem 505.

The substrate 504, stem 505 and radial projections 506 may be integrally formed (i.e., formed from a single piece of material). For ease of reference, the substrate 504, stem 505 and radial projections 506 may be referred to as a mirror body 503. The mirror body 503 may for example be formed from ceramic material such as silicon clad Silicone Carbide or may be a metal such as aluminium.

A clamp plate 508 is located between the substrate 504 and the radial projections 506. The clamp plate 508 may be formed from two parts which are fitted from either side of the stem. The clamp plate 508 may be formed from metal, e.g., Aluminium or Titanium. The clamp plate 508 presses against an upper surface of the radial projections 506. There is a gap between the stem 505 and the clamp plate 508. This configuration allows for thermal expansion of the stem 505 and may also allow for thermal expansion of the radial projections 506. Advantageously, applying the clamp plate 508 does not deform the substrate 504 or the reflective surface 502.

An encoder support 510 is provided below the radial projections 506. The encoder support 510 comprises a body 512 from which encoder arms 514 extend. The encoder support 510 may be formed from titanium (or other metal or ceramic). The encoder arms 514 extend radially outwards. An encoder scale 516 is provided on an outwardly oriented face of each encoder arm 514. The encoder scale 516 comprises a piece of glass which is fixed to the encoder arm 514 (e.g., using adhesive). A scale has been etched into the glass, for example using a laser. Other encoder scales may be used, as described further below.

An actuator yoke 518 is provided below the encoder support 510. The actuator yoke comprises a body and four actuator arms 522. The actuator yoke is formed from ferromagnetic material (e.g., soft magnetic composite, or cobalt-ferrite). The actuator arms 522 extend radially outwards. In the depicted embodiment the actuator arms are oriented at 45° relative to the encoder arms 514. However, in other embodiments the actuator arms 522 may have a different angle relative to the encoder arms 514.

A second clamp plate 524 is located beneath the actuator yoke 518. The second clamp plate 524 may be formed from metal, e.g., Aluminium or Titanium. Bolts 526 extend through the second clamp plate 524, actuator yoke 518, encoder support 510 and radial projections 506. The bolts 526 also extend through a flexure 546 (omitted from FIG. 3 but shown in FIG. 4). The bolts 526 are received in the first clamp plate 508. The bolts 526 are used to draw the first and second clamp plates 508, 524 together, thereby drawing together the different parts of the position-controllable mirror 501. This advantageously provides the moveable part 544 of the position-controllable mirror 501 with improved stiffness. The stiffness of the actuator yoke 518, for example, has an impact upon the accuracy of movement and the bandwidth of the position-controllable mirror 501. The clamp formed by the clamp plates 508, 524 is advantageous because it increases the rigidity of the actuator yoke 518 (compared with if no clamp was present). In general, the improved stiffness provided by the clamp may allow the position-controllable mirror 501 to move at higher frequencies (e.g., 1 kHz or more).

In the depicted embodiment eight bolts 526 are provided. However, a different number of bolts may be used.

A stator 530 is located below the actuator yoke 518. The stator 530 comprises four stator arms 532 which extend radially outwards. A pillar 534 extends upwardly from each stator arm 532. An electric coil 536 is provided around each pillar 534. For ease of illustration only one electric coil 536 is depicted. The electric coil is connected by wires 538 to a current source which may form part of a controller (not depicted). A central pillar 540 extends upwardly from a central portion of the stator 530. A permanent magnet 541 is provided on the pillar 540. The actuator 518, stator 530, permanent magnet 541 and coils 536 may comprise a hybrid reluctance actuator.

A bendable stem 542 supports the moveable part 544 of the position-controllable mirror 501. The bendable stem may be formed from metal, e.g., steel or Titanium. The bendable stem 542 is coaxial with a central axis A of the position-controllable mirror 501. An upper end of the bendable stem 542 is received by the encoder support 510. The bendable stem 542 extends through the actuator yoke 518, through the permanent magnet 541, and through the central pillar 540 of the stator 540. The bendable stem 542 is received and secured in a base (not depicted) located below the stator 530. The bendable stem 542 has some flexibility and thereby permits tilting of the moveable part 544 of the position-controllable mirror 501.

A flexure 546 is located between the radial projections 506 and the encoder support 510. The flexure 546 is described further below.

In use, when no current is provided to the electric coils 536, the position-controllable mirror 501 is in a neutral orientation. The neutral orientation may for example be with the reflective surface 502 being perpendicular to the central axis A. The pillars 534 enable the conduction of a magnetic field form the permanent magnet 541, and each pillar attracts a respective actuator arm 522 with the same attractive force. When current is supplied to an electric coil 536 on a pillar 534, that current generates an additional magnetic field. The additional magnetic field may augment the magnetic field provided by the pillar 534, thereby increasing the overall attractive magnetic field, in which case the actuator arm 522 moves towards that pillar. The additional magnetic field may be opposite to the magnetic field provided by the pillar 534, thereby reducing the overall attractive magnetic field, in which case the actuator arm 522 moves away from that pillar. Through supplying different current to different coils 536, any desired orientation and magnitude of tilt of the reflective surface 502 can be obtained.

A controller 490 (see FIG. 2) controls the current that is supplied to each electric coil 536 at each stator pillar 534. The controller 490 controls the tilt of the position-controllable mirror 501 using the current. The controller 490 thus moves the position-controllable mirror 501 to desired orientations.

As noted further above, the position-controllable mirror may be configured to reflect a laser beam with a wavelength of around 1 micron (e.g., 1.033-1.064 micron). The moveable parts 544 of the position-controllable mirror 501 may for example have a mass of up to 100 g. The moveable parts 544 of the position-controllable mirror 501 may for example have a mass of 30 g or more. This mass is relatively low compared with the mass of a mirror which is used to reflect a laser beam with a longer wavelength such as 10 microns. This is because the reflective surface 502 of the position-controllable mirror 501 has a relatively high reflectance (e.g., greater than 99.8%), and as a result does not experience a degree of heating due to laser radiation absorption. In comparison, a mirror configured to reflect laser radiation at around 10 microns will have a significantly lower reflectivity (e.g., around 98%) and as a result will absorb significant amounts of laser radiation. Such a mirror requires active cooling (e.g., water cooling) to avoid the mirror overheating. The active cooling components add a considerable weight to the mirror. Because the position-controllable mirror 501 does not include active cooling (e.g., water cooling) it has a relatively low mass.

Prior art pre-pulse laser systems use a relatively high mass position-controllable mirror. In embodiments of the disclosure, the moveable parts of the position-controllable mirror 501 have a mass of up to 100 g. The moveable parts 544 of the position-controllable mirror 501 may for example have a mass of 30 g or more. Because the position-controllable mirror 501 has a relatively low mass, it allows for better dynamic performance compared with a higher mass mirror. The bandwidth with which the position-controllable mirror 501 can be controlled is higher than for a mirror with a higher mass. The bandwidth of control for the position-controllable mirror 501 of embodiments of the disclosure may for example be 500 Hz or more, e.g., 1 kHz or more.

A control bandwidth of 1 kHz or more is particularly advantageous because it allows for feedback control to correct for plasma-disturbances of the position of fuel droplets in the EUV radiation source. Plasma-disturbance occurs when a plasma generated from a fuel droplet has an effect upon the trajectory of the next fuel droplet. This disturbance of the fuel droplet position by the plasma occurs with a frequency range of between 200 and 300 Hz. When the position-controllable mirror 501 has a bandwidth of at least 1 kHz, this allows the position of the pre-pulse laser beam to be controlled such that it compensates for fuel droplet movements caused by plasma-disturbances. As a result, laser beam pre-pulses are incident upon fuel droplets with greater accuracy. This increases the efficiency with which EUV radiation is generated by the EUV radiation source. In general, the bandwidth of the position-controllable mirror 501 may be at least two times greater than a frequency of plasma disturbances. The bandwidth of the position-controllable mirror 501 may be at least three times greater than a frequency of plasma disturbances. A bandwidth of at least 500 Hz may be sufficient to compensate for most plasma-disturbances, and thereby provide an improvement over conventional systems. A bandwidth of at least 1 kHz may be preferred in order to ensure that all plasma-disturbances can be compensated for.

The position-controllable mirror 501 may for example have a tilt range of at least 10 mrad. The position-controllable mirror 501 may for example have a tilt range of up to 20 mrad. Although this is a relatively small range, the range may be sufficient to correct for deviations of the fuel droplet position from a nominal position. The position-controllable mirror may for example have a diameter of up to 2 cm, e.g., up to 4 cm. This is a relatively small diameter (compared with some prior art mirrors) and helps to keep the mass of the position-controllable mirror relatively low.

In an embodiment the actuator yoke 518 and/or the stator 530 may be formed from soft magnetic composite (SMC). The actuator yoke 518 may be formed as a single monolithic part. The stator 530 may be formed as a single monolithic part (e.g., including the pillars 534). The use of SMC is advantageous because it reduces the formation of Eddy currents within the yoke actuator 518 and the stator 530 (compared with conventional ferromagnetic material). Eddy currents will degrade performance (i.e., reduce the bandwidth of operation) of the position-controllable mirror 501. The SMC may be formed from ferromagnetic powder which has been coated with electrically insulating material. SMCs have a lower electrical conductivity than ferromagnetic material (thereby reducing eddy current) but have a coercivity, permeability and magnetic flux density that allow operation at a bandwidth of 1 kHz or more. The SMC may for example be Somaloy, available from Hoganas AB, Sweden.

In an alternative arrangement, the actuator yoke 518 and/or the stator 530 may be formed from laminated ferrous material (e.g., laminated cobalt ferrite). An example of this arrangement is depicted in FIG. 5. As depicted in FIG. 5, the actuator yoke 518 comprises a plurality of layers of cobalt ferrite which are secured together using insulating adhesive. The insulating adhesive may for example have relatively low outgassing characteristics compared with conventional adhesive. The adhesive may for example be Remisol EB 549, available from Rembrandtin Coatings GmbH of Vienna, Austria. The laminations are perpendicular to the axis A of the position-controllable mirror 501. Thus, in the depicted arrangement the laminations of the actuator yoke 518 are horizontal. The actuator yoke 518 may for example be formed by constructing a laminated structure which is wider than required, and then removing material using laser cutting, electrical discharge machining, or some other machining process.

The stator 530 comprises stator arms 532 and pillars 534. The laminations of the stator arms 532 along with a central portion of the stator are perpendicular to the central axis A of the position-controllable mirror 501. As with the actuator yoke 518, the laminations of the stator 530 may be formed from cobalt ferrite layers which are glued together using an insulating adhesive. Again, the insulating adhesive may have relatively low outgassing. An example of the insulating adhesive is Remisol EB 549. The stator 530 may for example be formed by constructing a laminated structure which is wider than required, and then removing material using laser cutting or some other machining process.

The pillars 534 are laminated in a direction which is parallel with the central axis A of the position-controllable mirror 501. The laminations of the pillars 534 are thus perpendicular to the laminations of the stator arms 532. The pillars 534 may for example be formed by constructing laminated pillars which are wider than required, and then removing material using laser cutting or other machining process.

The pillars 534 are received in openings 535 in the stator arms 532. The openings 535 pass fully through the stator arms 532 such that a portion of each pillar 534 may project out of a bottom surface of the stator arms 532. This advantageously allows the height of each pillar 534 to be adjusted during construction such that it provides a desired gap to the actuator yoke 518. The pillars 534 may be glued in position in the stator arms 532.

The central pillar 540 is also formed as a laminated structure. The laminations of the central pillar 540 are parallel with the central axis A of the position-controllable mirror 501. In common with other arrangements, the central pillar 540 is annular in order to accommodate the bendable stem 542. A permanent magnet 541 is provided on the central pillar 540.

One or more components of the position-controllable mirror 501 may be constructed using 3D printing (also referred to as additive manufacturing). For example, the substrate 504 may include one or more hollow volumes. This advantageously reduces the mass of the moveable part 544 of the mirror. Reducing the mass of the moveable part 544 of the mirror will increase eigenfrequencies of the position-controllable mirror 501. The bandwidth of operation of the position-controllable mirror 501 may be increased. Additionally, or alternatively, position-controlling may be achieved using a reduced amount of power.

Additive manufacturing may be used to form one or more hollow volumes in the encoder support 510. This advantageously reduces the mass of the moveable part 544 of the mirror. One or more hollow volumes may be formed in other components of the moveable part 544 of the mirror.

When a hollow volume is formed in a component of a moveable part 544 of the position-controllable mirror 501, that hollow volume may be fully enclosed. This may advantageously provide better rigidity than if the hollow volume were open, thereby allowing more accurate control of mirror tilting.

Internal structure such as ribs may be provided within a hollow volume in order to provide better rigidity.

Additive manufacturing may be used to provide one or more undercuts. Additive manufacturing may be used to provide a variable wall thickness.

Encoder scales may be applied to a side wall of the mirror substrate 504 (e.g., using laser engraving and/or etching). Where this is done, the encoder support 510 is no longer required. Since the encoder support 510 contributes significant mass to the position-controllable mirror 501, omitting the encoder support will reduce mass of the position-controllable mirror. This may increase the eigenfrequencies and the bandwidth of the position-controllable mirror 501.

In other embodiments the encoder scale may be provided on the side wall of the mirror substrate 504 using other techniques. In one example, the encoder scale may be engraved into a side wall of the mirror substrate 504.

Encoder heads (not depicted) may be located adjacent to the encoder scales. The encoder heads may have a conventional construction, being configured to shine radiation through a grating. The grating pattern of radiation forms an interference pattern with the encoder grating, and an optical detector of the encoder head measures position using the interference pattern.

In the embodiment depicted in FIGS. 3 and 4, the encoder scales 516 are provided on pieces of glass. In an alternative arrangement, the encoder scales may be formed directly on the encoder arms 514. This may advantageously remove thermal instability that may arise from adhesive provided between the glass encoder scales and the encoder arms. Furthermore, it may reduce the mass of the moveable part 544 of the position-controllable mirror 501.

The encoder scales 516 may be flat, as depicted. Alternatively, the encoder scales may be convex. The encoder scales may be provided with a radius of curvature which generally corresponds with a radial distance from the encoder scales to the central axis A of the position-controllable mirror 501. A convex encoder scale is advantageous because this will reduce or eliminate changes of a separation distance between the encoder scale and an encoder head that would otherwise occur due to tilting movement of the position-controllable mirror 501. This allows the position of the moveable part 544 of the mirror to be controlled more accurately and/or over a larger range of movement.

As noted further above, the encoder scales may be provided on a side wall of the mirror substrate 504. The side wall of the mirror substrate 504 may be convex. The side wall of the mirror substrate 504 may be provided with a radius of curvature which generally corresponds with a radial distance from the encoder scales to the central axis A of the position-controllable mirror 501. This allows the position of the moveable part 544 of the mirror to be controlled more accurately and/or over a larger range of movement.

Four encoders may be provided, each comprising an encoder scale 516 and an encoder head (not depicted). The four encoders may be angularly separated from each other by 90°, thereby providing four-fold symmetry. Providing four encoders is advantageous because it allows the controller to discriminate and account for encoder signals arising from unwanted movement of the moveable part 544 of the position-controllable mirror 501. For example, movement along the direction of the central axis A may be discriminated from tilting. Using four encoders also allows the controller to discriminate and account for thermal expansion and contraction of mirror components which may occur during use.

Less than four encoders may be used. However, using four encoders may provide a measurement stability of 25 μrad (compared with measurement stability of 250 μrad if three encoders are used). Two encoders may be used, but this will further reduce measurement stability.

The position-controllable mirror may provide an angular resolution accuracy of around 0.1 μrad or better.

Using encoders to monitor the position of the moveable part 544 of the position-controllable mirror 501 is advantageous because the encoders are able to provide a response bandwidth of 1 kHz or more. Such a response bandwidth may not be achievable for example if eddy current sensors were to be used (as is conventional). Furthermore, encoders are able to provide better accuracy and/or range than eddy current sensors.

In an embodiment (not depicted), the position controllable mirror may include a heat dump. The heat dump may comprise a sheet of metal provided between the mirror substrate 504 and the actuator yoke 518. The sheet of metal may assist with thermal management of the moveable part 544 of the position-controllable mirror 501. Flexible metal connections may extend from the mirror substrate 504 to the sheet of metal. The flexible metal connections conduct heat from the mirror substrate 504 to the sheet of metal.

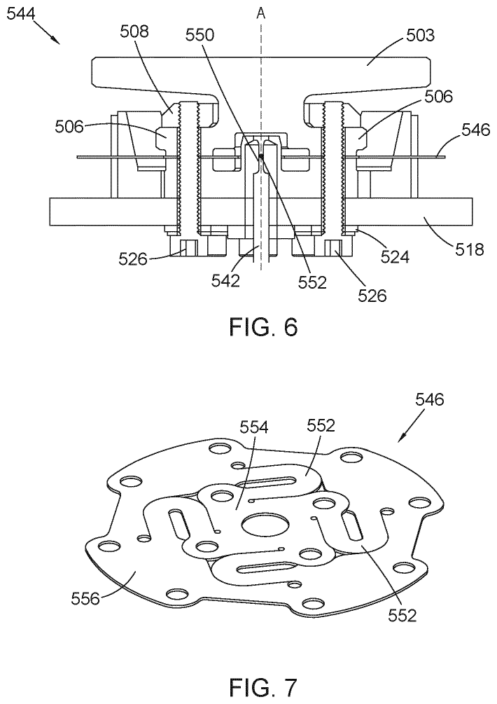

FIG. 6 depicts in cross section the moveable part 544 of the position-controllable mirror 501, and FIG. 7 is a perspective view of the flexure 546 which is located between the encoder support 510 and the radial projections 506.

Features of the moveable part 544 of the position-controllable mirror 501 which are more easily understood with reference to FIGS. 6 and 7 than preceding figures are described below.

The bolts 526 extend through second clamp plate 524, the actuator yoke 518, the encoder support 510, the flexure 546, and the radial projections 506 of the mirror body 503. The bolts 526 are received in the first clamp pate 508. The first clamp plate 508 is threaded such that the bolts 526 can be screwed into the first clamp plate. The other components 524, 518, 510, 546, 506 through which the bolts 526 pass are not threaded. Instead, there is a clearance between the bolts and the components. This clearance allows for some thermal expansion and contraction of the components, without the bolt transmitting that thermal expansion or contraction to other components. For example, the radial projections 506 may expand with respect to the flexure 546. The radial projections 506 may slide over the flexure 546 without the bolts 526 transmitting the expansion to the flexure.

The bendable stem 542 includes a narrowed diameter portion 550. The narrowed diameter portion 550 is located adjacent to an upper end of the bendable stem. The bendable stem 542 preferentially bends at the narrowed diameter portion 550. A centre of gravity 552 of the moveable part 544 of the position-controllable mirror 501 is identified by a disc. The centre of gravity 552 is aligned with the central axis A of the moveable part 544 of the position-controllable mirror 501. The centre of gravity 552 is located in the narrowed diameter portion 550 of the bendable stem 542. In an embodiment, the centre of gravity 552 may be aligned with the flexure 546 (e.g., as depicted).

The centre of gravity 552 of the moveable part 544 of the position-controllable mirror 501 may correspond with a centre of elasticity of the moveable part (i.e., the position about which the moveable part 544 tilts). Providing the centre of elasticity at the centre of gravity 552 is advantageous because this decouples translational modes of the moveable part 544 from unwanted rotational modes of the moving part.

The flexure 546 comprises a plate. The plate may for example be formed from metal, for example Stavax stainless steel. An inner portion 554 of the flexure 546 is secured between the encoder support 510 and the radial projections 506 of the mirror 503 body. An outer portion 556 of the flexure engages with a housing of the actuator (the housing being fixed and not part of the moveable part 544 of the position-controllable mirror 501). The flexure 546 may be configured to eliminate or reduce unwanted movement of the mirror 503 body.

In an example, the flexure 546 may reduce a tendency for the moveable part 544 to rotate around the central axis A when a tilt is applied (this may be caused by thermal expansion of components of the moveable part). This is achieved by U-shaped connections 552 which extend from the inner portion 554 of the flexure to the outer portion 556 of the flexure. If a straight connection were provided between the inner and outer portions 554, 556 of the flexure 546, then thermal expansion could cause unwanted rotation of the mirror body 503 during tilting. The U-shaped connections 552 prevent or reduce rotation being caused when a tilt occurs. Although a U-shaped connection 552 is depicted, connections which include a bend may be used.

A clearance is provided between the bendable stem 542 and the actuator yoke 518. Similarly, a clearance is provided between the bendable stem 542 and the encoder support 510. The clearance allows tilting of the moveable part 544 to occur without an inner wall of the actuator yoke 518 or encoder support 510 contacting the bendable stem 542.

The permanent magnet 541 provides a magnetic field which extends along the actuator arms 522, along the pillars 534 and along the stator arms 532. The electromagnets formed by the coils 536 add to or reduce the magnetic field provided by the permanent magnet 541, thereby tilting the mirror body 503 (as explained further below). The permanent magnet 541 may for example provide a magnetomotive force of around 7000 A. The permanent magnet 541 may have a reluctance for example of 1.5e8 1/He.

The length of the bendable stem 542 may be selected such that a gap exists between the lowermost surfaces of the arms 518 of the yoke actuator 510 and uppermost surfaces of the pillars 534 of the stator 530. The gap may be selected to provide a desired amount of angular rotation to be achieved (e.g., up to +/−10 mrad). The gap may be for example at least 0.2 mm. The gap may for example be up to 0.7 mm. A gap of more than 0.7 mm be less preferred, because the increased gap reduces the force which is applied by the stator 530 for a given current supplied to the coils 536.

A gap also exists between the permanent magnet 541 and a lowermost surface of the actuator yoke 518 In an embodiment, the position-controllable mirror may include adjustable end stops (not depicted). The adjustable end stops may for example comprise bolts which extend upwardly from a non-moving part of the position-controllable mirror 501. Upper ends of the bolts may be positioned such that they are aligned with the encoder arms 514. The upper ends of the bolts may be arranged such that a lowermost surface of an encoder arm comes into contact with an upper end of a bolt when the tilt of the moveable part 544 reaches the end of the desired range. The position of the end of each bolt may be adjusted by screwing the bolt upwards and downwards in the non-moving part.

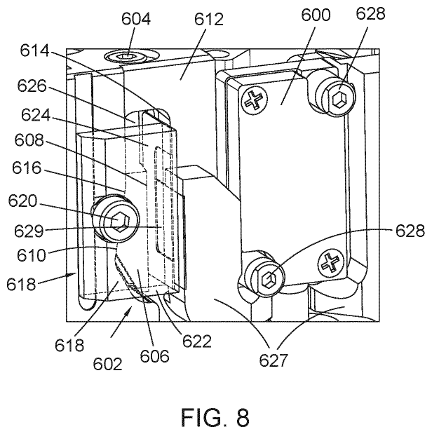

FIG. 8 depicts in perspective view an encoder head 600 and locking system 602 which may form part of an embodiment of the invention. The encoder head 600 and locking system 602 may form part of a position-controllable mirror 501 according to an embodiment of the invention. The encoder head 600 may be one of four encoder heads, each encoder head being provided adjacent to a respective encoder scale 516 (encoder scales are depicted for example in FIG. 4).

The vertical position of the encoder head 600 is adjustable. This allows the encoder head to located at a desired vertical position with respect to an associated encoder scale 516.

A locking system 602 is also shown in FIG. 8. The locking system 602 is configured to lock the encoder head 600 in place once the encoder head has been moved to a desired vertical position. Locking the encoder head 600 in place is desirable because once the encoder head is locked in place it will not move in a vertical direction and thus will maintain measurement accuracy. In addition, locking the encoder head 600 in place will give the encoder head a higher stiffness compared with when the encoder head is not locked in place. The higher stiffness advantageously helps to achieve a desirable control bandwidth of at least 500 Hz. If the encoder head 600 were to have a lower stiffness, then it could have an eigenfrequency below 500 Hz. In such a case this could reduce the control bandwidth of the position-controllable mirror 501 to below 500 Hz.

The locking system 602 comprises a bolt 604 onto which a chamfered block 606 is threaded. The chamfered block 606 and bolt 604 form an actuator (other forms of actuator may be used). The chamfered block 606 has a vertical side 608 which faces towards the encoder head 600 and has an angled side 610 which faces away from the encoder head 600. The bolt 604 and the chamfered block 606 are received within an opening 626 in a housing 612. The housing may be a housing of the position-controllable mirror 501. The opening 626 in the housing 612 includes a vertical wall 614 which faces the vertical side 608 of the chamfered block 606. The housing 612 further comprises an angled wall 616 which faces the angled side 610 of the chamfered block 606.

The locking system 602 further comprises a locking member 618. The locking member 618 comprises a body 622 which is secured to the housing 612 by a bolt 620. The locking member 618 further comprises a leaf spring 624 which extends into the opening 626 in the housing 612. The leaf spring 624 lies in a plane which is generally parallel the central axis A of the position-controllable mirror 501 (see FIG. 4). The leaf spring 624 may extend in a generally radial direction relative to the central axis A of the position-controllable mirror 501.

The encoder head 600 is secured to an encoder head holder 627. The encoder head 600 is fixed to the holder 627 by bolts 628. When the vertical position of the encoder head 600 is selected, the holder 627 and the encoder head 600 are moved together. The holder 627 may include one or more protrusions which are received in one or more grooves (not depicted) of the housing 612.

The encoder head holder 627 includes a plate 629 which extends into the opening 626 of the housing 612. The plate 629 lies in a plane which is generally parallel with the central axis A of the position-controllable mirror. The plate 629 may lie in a plane which extends in a radial direction from the central axis A of the position-controllable mirror. The plate 629 is sandwiched between the leaf spring 624 and the housing vertical wall 614.

In use, when the bolt 604 is turned in the clockwise direction, this draws the chamfered block 606 upwards. The angled side 610 of the chamfered block 606 cams against the angled wall 616 of the housing. This camming of the angled side 610 against the angled wall 616 causes the chamfered block 606 to move towards the encoder head 600. A vertical side 608 of the chamfered block 606 moves towards the housing vertical wall 614. The vertical side 608 of the chamfered block 606 presses the leaf spring 624 and the plate 628 against the housing vertical wall 614. This clamps the encoder head holder 627 to the housing vertical wall 614 such that it is rigidly secured in place. Thus, the encoder head 600, which is secured to the encoder head holder 627, is also rigidly secured in place.

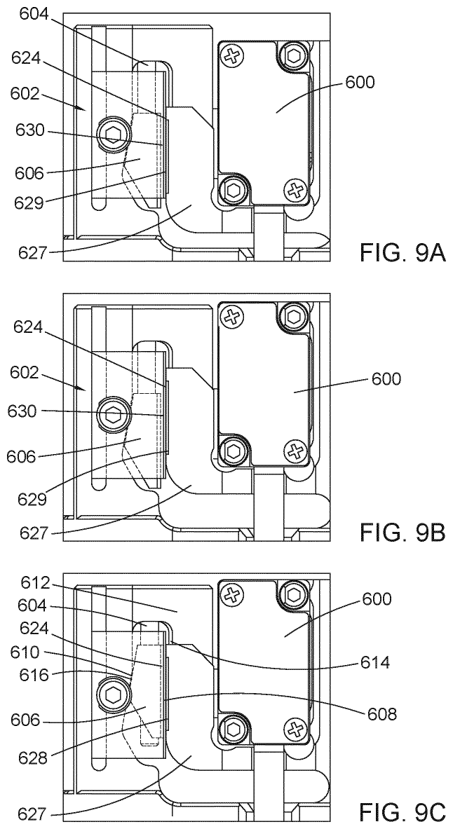

FIGS. 9A-C depict adjustment of the height of the encoder head 600 and locking of the encoder head in position.

FIG. 9A depicts the encoder head 600, encoder head holder 627, housing 612, and locking system 602 viewed from one side. In FIG. 9A the encoder head is below a desired vertical position. The bolt 604 has been rotated such that the chamfered block 606 is not pressing against the leaf spring 624 or the plate 629. There is a gap 630 between the chamfered block 606 and the leaf spring 624.

Referring to FIG. 9B, the encoder head 600 and encoder head holder 627 have been moved upward to a desired position. The chamfered block 606 again is not pressing against the leaf spring 624 or the plate 629. The gap 630 remains between the chamfered block 606 and the leaf spring 624.

Referring to FIG. 9C, the bolt 604 has been rotated. Rotating the bolt 604 has drawn the chamfered block 606 upwards. The angled side 610 of the chamfered block 606 is engaged with the angled wall 616 of the housing 612, thereby pushing the chamfered block towards the encoder head 600 in a camming motion. The bolt 604 has been turned until the vertical side 608 of the chambered block 606 presses the leaf spring 624 and the encoder head holder plate 629 against the housing vertical wall 614. This secures the encoder head holder 627 and encoder 600 in place.

Advantageously, although the chamfered block 606 is moving vertically when it engages with the leaf spring 624, it does not transmit parasitic vertical force to the encoder head 600. This is because the leaf spring 624 acts to decouple horizontal force and vertical force when it is engaged by the chamfered block 606.

According to an aspect of the invention there is provided an encoder head and locking system, wherein the locking system comprises a leaf spring which is bendable in a direction perpendicular to an adjustment direction of the encoder head.

The position-controllable mirror may be configured for use in a vacuum environment. Components of the position-controllable mirror may be formed from metal, ceramic or glass, which do not suffer from significant outgassing. As noted further above, the adhesive may have relatively low outgassing characteristics compared with conventional adhesive.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin film magnetic heads, etc.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

While specific embodiments of the invention have been described above, it will be appreciated that the invention may be practiced otherwise than as described. The descriptions above are intended to be illustrative, not limiting. Thus, it will be apparent to one skilled in the art that modification may be made to the invention as described without departing from the scope of the claims set out below.

### CLAUSES

1. An EUV radiation source comprising a laser configured to emit a laser beam, and an optical system configured to control a position of the laser beam such that it is incident upon fuel droplets, wherein the optical system comprises an optical path which includes a position-controllable mirror having a control bandwidth of at least 500 Hz.
2. The EUV radiation source of clause 1, wherein the position-controllable mirror has a control bandwidth of at least 1 kHz.
3. The EUV radiation source of clause 1 or clause 2, further comprising a controller configured to control tilt of the position-controllable mirror, wherein the controller is configured to control the position-controllable mirror to at least partially compensate for laser beam position errors arising from an actuatable optical device in the optical path which has a lower bandwidth of control than the position-controllable mirror.
4. The EUV radiation source of any preceding clause, wherein the position-controllable mirror comprises a plurality of optical encoders.
5. The EUV radiation source of clause 4, wherein the optical encoders include encoder scales provided on radially extending arms of an encoder support.
6. The EUV radiation source of clause 4, wherein the optical encoders include encoder scales provided on a side wall of a mirror substrate of the position-controllable mirror.
7. The EUV radiation source of any of clauses 4 to 6, wherein the encoder scales are convex.
8. The EUV radiation source of clause 7, wherein the encoder scales have a radius of curvature which generally corresponds with a radial distance from the encoder scales to a central axis of the position-controllable mirror.
9. The EUV radiation source of any preceding clause, wherein the position-controllable mirror comprises a hybrid reluctance actuator formed from an actuator yoke and a stator, each of which comprises a plurality of radially extending arms.
10. The EUV radiation source of clause 9, wherein at least one of the actuator yoke and the stator is formed from soft magnetic composite.
11. The EUV radiation source of clause 10, wherein the stator is formed from soft magnetic composite, and the stator further comprises pillars which extend perpendicularly from the radially extending stator arms, the pillars being integrally formed with the radially extending arms.
12. The EUV radiation source of clause 9, wherein at least one of the actuator yoke and the stator is formed from laminated ferrous material.
13. The EUV radiation source of clause 12, wherein laminations of the radially extending arms of the stator are perpendicular to a central axis of the position-controllable mirror.
14. The EUV radiation source of clause 13, wherein the stator further comprises pillars which extend perpendicularly from the radially extending arms, and wherein laminations of the pillars are parallel with the central axis of the position-controllable mirror.
15. The EUV radiation source of clause 14, wherein the pillars extend through openings provided in the radially extending stator arms.
16. The EUV radiation source of any preceding clause, wherein the position-controllable mirror further comprises a clamp configured to clamp together the actuator yoke and radial projections which project from a stem of the mirror.
17. The EUV radiation source of clause 16, wherein the clamp also clamps an encoder support together with the actuator yoke and the radial projections which project from the stem of the mirror.
18. The EUV radiation source of any preceding clause, wherein the mirror comprises a substrate provided with a reflective surface, and wherein the mirror substrate comprises at least one of: one or more hollow volumes, one or more undercuts, a variable wall thickness.
19. The EUV radiation source of any preceding claim, wherein the position-controllable mirror further comprises a bendable stem which connects the mirror to a base.
20. The EUV radiation source of clause 19, wherein the bendable stem has a narrowed diameter portion.
21. The EUV radiation source of clause 20, wherein a centre of gravity of a moveable part of the position-controllable mirror is located at the narrowed diameter portion of the bendable stem.
22. The EUV radiation source of any preceding clause, wherein a centre of gravity of a moveable part of the position-controllable mirror corresponds with a centre of elasticity of the moveable part of the position-controllable mirror.
23. The EUV radiation source of any preceding clause, wherein the position-controllable mirror further comprises a flexure located below the mirror and above the actuator yoke.
24. The EUV radiation source of clause 23, wherein the flexure comprises a plurality of connections between an inner portion and an outer portion, the connections including a bend.
25. The EUV radiation source of clause 24, wherein the flexure comprises a plurality of connections between an inner portion and an outer portion, the connections being U-shaped.
26. The EUV radiation source of any preceding clause, wherein the position-controllable mirror is configured for use in a vacuum environment.
27. The EUV radiation source of any preceding clause, wherein a mirror body of the position controllable mirror is formed from ceramic material.
28. The EUV radiation source of any preceding clause, wherein the position-controllable mirror includes adjustable end stops.
29. The EUV radiation source of any preceding clause, wherein the position controllable mirror includes a heat dump.
30. The EUV radiation source of any preceding clause, further comprising an encoder head and locking system, wherein the locking system comprises a leaf spring and an actuator, the actuator being configured to engage the leaf spring with an encoder head holder, wherein the leaf spring lies in a plane which is generally parallel to a central axis of the position-controllable mirror.
31. The EUV radiation source of clause 30, wherein the encoder head holder further comprises a plate configured to be sandwiched between the leaf spring and a housing wall of the position-controllable mirror.
32. The position controllable mirror of clause 31, wherein the actuator comprises a chamfered block which is threadingly engaged with a bolt, the chamfered block being located within an opening in the housing wall.
33. A position-controllable mirror for use in an EUV radiation source, wherein the position-controllable mirror has a control bandwidth of at least 500 Hz.
34. A method of directing a laser beam onto a fuel droplet in an EUV radiation source, wherein the method comprises controlling the position of the laser beam using a position-controllable mirror having a control bandwidth of at least 500 Hz.
35. The method of clause 34, wherein the position controllable mirror is in an optical path together with at least one actuatable optical device, and wherein the position-controllable mirror is tilted to at least partially compensate for laser beam position errors arising from a lower control bandwidth of the actuatable optical device compared with the control bandwidth of the position-controllable mirror.

1-19. (canceled)

20. An EUV radiation source comprising:
a laser configured to emit a laser beam, and
an optical system configured to control a position of the laser beam such that it is incident upon fuel droplets,
wherein the optical system comprises an optical path which includes a position-controllable mirror having a control bandwidth of at least 500 Hz.

21. The EUV radiation source of claim 20, wherein the position-controllable mirror has a control bandwidth of at least 1 kHz.

22. The EUV radiation source of claim 20, further comprising:
a controller configured to control tilt of the position-controllable mirror,
wherein the controller is configured to control the position-controllable mirror to at least partially compensate for laser beam position errors arising from an actuatable optical device in the optical path which has a lower bandwidth of control than the position-controllable mirror.

23. The EUV radiation source of claim 20, wherein:
the position-controllable mirror comprises a plurality of optical encoders,
the optical encoders include encoder scales provided on radially extending arms of an encoder support, and
the optical encoders include encoder scales provided on a side wall of a mirror substrate of the position-controllable mirror.

24. The EUV radiation source of claim 23, wherein the encoder scales are convex such that the encoder scales have a radius of curvature which generally corresponds with a radial distance from the encoder scales to a central axis of the position-controllable mirror.

25. The EUV radiation source of claim 20, wherein the position-controllable mirror comprises a hybrid reluctance actuator formed from an actuator yoke and a stator, each of which comprises a plurality of radially extending arms.

26. The EUV radiation source of claim 25, wherein:
at least one of the actuator yoke and the stator is formed from soft magnetic composite, and
the stator further comprises pillars which extend perpendicularly from the radially extending stator arms, the pillars being integrally formed with the radially extending arms.

27. The EUV radiation source of claim 25, wherein:
at least one of the actuator yoke and the stator is formed from laminated ferrous material,
laminations of the radially extending arms of the stator are perpendicular to a central axis of the position-controllable mirror,
the stator further comprises pillars which extend perpendicularly from the radially extending arms, and
laminations of the pillars are parallel with the central axis of the position-controllable mirror, and further wherein the pillars extend through openings provided in the radially extending stator arms.

28. The EUV radiation source of claim 20, wherein:
the position-controllable mirror further comprises a clamp configured to clamp together the actuator yoke and radial projections which project from a stem of the mirror, and
the clamp also clamps an encoder support together with the actuator yoke and the radial projections which project from the stem of the mirror.

29. The EUV radiation source of claim 20, wherein:
the mirror comprises a substrate provided with a reflective surface, and
the mirror substrate comprises one or more hollow volumes, one or more undercuts, and/or a variable wall thickness.

30. The EUV radiation source of claim 20, wherein:
the position-controllable mirror further comprises a bendable stem which connects the mirror to a base,
the bendable stem has a narrowed diameter portion, and
a center of gravity of a moveable part of the position-controllable mirror is located at the narrowed diameter portion of the bendable stem.

31. The EUV radiation source of claim 20, wherein a center of gravity of a moveable part of the position-controllable mirror corresponds with a center of elasticity of the moveable part of the position-controllable mirror.

32. The EUV radiation source of claim 20, wherein:
the position-controllable mirror further comprises a flexure located below the mirror and above the actuator yoke,
the flexure comprises a plurality of connections between an inner portion and an outer portion, the connections including a bend, and
the flexure comprises a plurality of connections between an inner portion and an outer portion, the connections being U-shaped.

33. The EUV radiation source of claim 20, wherein the position-controllable mirror is any one or more of:
configured for use in a vacuum environment;
includes adjustable end stops; and/or
includes a heat dump.

34. The EUV radiation source of claim 20, wherein a mirror body of the position controllable mirror is formed from ceramic material.

35. The EUV radiation source of claim 20, further comprising:
an encoder head and locking system,
wherein the locking system comprises a leaf spring and an actuator, the actuator being configured to engage the leaf spring with an encoder head holder,
wherein the leaf spring lies in a plane which is generally parallel to a central axis of the position-controllable mirror, and
wherein the encoder head holder further comprises a plate configured to be sandwiched between the leaf spring and a housing wall of the position-controllable mirror.

36. A position-controllable mirror for use in an EUV radiation source, wherein the position-controllable mirror has a control bandwidth of at least 500 Hz.

37. A method of directing a laser beam onto a fuel droplet in an EUV radiation source, wherein the method comprises:
controlling the position of the laser beam using a position-controllable mirror having a control bandwidth of at least 500 Hz.

38. The method of claim 37, wherein:
the position controllable mirror is in an optical path together with at least one actuatable optical device, and
the position-controllable mirror is tilted to at least partially compensate for laser beam position errors arising from a lower control bandwidth of the actuatable optical device compared with the control bandwidth of the position-controllable mirror.
